(19) United States
(12) Patent Application Publication
(10) Pub. No.: US 2026/0283045 A1
(43) Pub. Date: Sep. 17, 2026

(54) ELEVATED INTERPOSER FOR WIRE BONDING IN STACKED SEMICONDUCTOR DEVICES, AND ASSOCIATED SYSTEMS AND METHODS

(71) Applicant: Micron Technology, Inc., Boise, ID (US)

(72) Inventors: Wen Wei Lum, Singapore (SG); Seng Kim Ye, Singapore (SG); Kelvin Tan Aik Boo, Singapore (SG); Hong Wan Ng, Singapore (SG)

(21) Appl. No.: 19/532,982

(22) Filed: Feb. 6, 2026

Related U.S. Application Data
(60) Provisional application No. 63/773,044, filed on Mar. 17, 2025.

(51) Int. Cl. H10W 90/24; H10W 72/00; H10W 90/00; H10W 90/10

(52) U.S. Cl. CPC H10W 90/24; H10W 72/015; H10W 90/10; H10W 90/752; H10W 90/754

(57) ABSTRACT

Stacked semiconductor devices and associated systems and methods are disclosed herein. For example, a stacked semiconductor device according to the present technology can include a base substrate, a controller die, an interposer substrate positioned directly over the controller die, and a plurality of dies carried by the base substrate adjacent to the controller die. The plurality of dies can include a first tier and a second tier carried by the first tier. The first tier includes a plurality of first dies staggered in a first direction, and each of the plurality of first dies is electrically coupled to the active surface via first wire bonds. The second tier includes a plurality of second dies staggered in a second direction, and each of the plurality of second dies is electrically coupled to an upper surface of the interposer substrate via second wire bonds.

### CROSS-REFERENCE TO RELATED APPLICATION(S)

The present application claims priority to U.S. Provisional Patent Application No. 63/773,044, filed March 17, 2025, the disclosure of which is incorporated herein by reference in its entirety.

### TECHNICAL FIELD

The present technology is generally directed to stacked semiconductor devices and more specifically to an elevated redistribution layer interposer for stacked semiconductor devices.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller and/or more dense devices. To meet market demands, semiconductor devices are being pushed to the limit with various improvements. Improving devices, generally, may include increasing circuit density, increasing circuit capacity, increasing operating speeds (or otherwise reducing operational latency), increasing reliability, including additional dies in semiconductor packages, reducing power consumption, or reducing manufacturing costs, among other metrics. Attempts, however, to meet market demands, such as by reducing the overall device footprint, can often introduce challenges in other aspects, such as maintaining circuit robustness and/or failure detectability.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1 is a partially schematic cross-sectional view of a stacked semiconductor device with multiple single-tier die stacks.

FIG. 2 is a partially schematic cross-sectional view of a stacked semiconductor device with multi-tiered die stacks.

FIG. 3 is a partially schematic cross-sectional view of a stacked semiconductor device configured in accordance with embodiments of the present technology.

FIG. 4 is a flow diagram of a process for manufacturing a stacked semiconductor device in accordance with embodiments of the present technology.

FIG. 5 is a partially schematic cross-sectional view of a stacked semiconductor device configured in accordance with embodiments of the present technology.

FIG. 6 is a schematic view of a system that includes a semiconductor package configured in accordance with embodiments of the present technology.

### DETAILED DESCRIPTION

As discussed in more detail below, the present disclosure is directed to stacked semiconductor devices that include an intermediate redistribution interposer and/or wing-shaped die stacks, and related systems and methods. For example, a stacked semiconductor device according to the present technology can include a base substrate that has an active surface (e.g., an upper surface, a front surface, and/or the like), as well as a controller, an interposer substrate, and a plurality of dies each carried by the active surface. The plurality of dies (e.g., memory dies, such as DRAM dies, NAND dies, and/or the like) can be stacked into multiple-tiered die stacks. Each of the tiers can be staggered (e.g., with each die offset from the die below it) in different directions. For example, a first portion (e.g., a first tier) of a die stack can be staggered in a first direction while a second portion (e.g., a second tier) is staggered in a second direction opposite to the first direction. As a result, the die stack can have a wing-shaped cross-sectional profile.

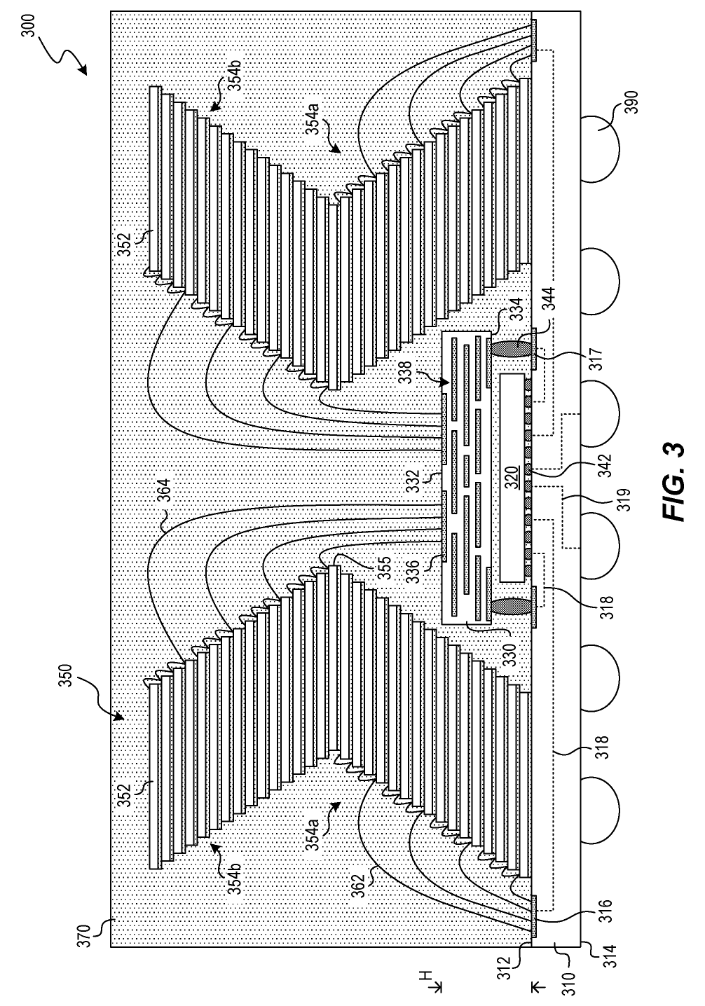

As also discussed in more detail below, the interposer substrate and the wing-shaped construction of the die stacks can help reduce a wire bond length within the stacked semiconductor device. For example, the interposer substrate can be positioned directly over the controller. Further, the first portion of the die stack can be integrated with the active surface of the base substrate via a first set of wire bonds, while the second portion can be integrated with an upper surface of the interposer substrate. Because the upper surface of the interposer substrate is at an elevation above the active surface, the second set of wire bonds can have a shorter length than if the second set of wire bonds were integrated with the active surface. Additionally, the wing-shaped profile of the die stacks and the position of the interposer substrate allow the first and second sets of wire bonds to be in different locations, thereby helping reduce wire sweep issues for large die stacks (e.g., stacks of more than eight dies). Still further, the interposer substrate (e.g., a redistribution layer (“RDL”) interposer) can provide additional space for route lines for trace matching, thereby creating a three-dimensional (3D) trace-matching scheme for the stacked semiconductor device. As a result of each of the benefits discussed above, the stacked semiconductor packages disclosed herein can help package more dies into a given longitudinal footprint for a semiconductor package. Additional details on the examples of the present technology are discussed below with reference to FIGS. 3–5.

Although the systems and methods discussed herein are discussed primarily with reference to a redistribution interposer for a shingle-stacked semiconductor device, one of skill in the art will understand that the processes of the present technology discussed herein are not so limited. Purely by way of example, the redistribution interposer and wire bonding schemes of the present technology can be utilized in other semiconductor packages to reduce the length of wire bonds, form a three-dimensional bonding scheme for trace-matching, and/or provide additional solid structures to improve the stability of the semiconductor devices. Accordingly, the scope of the invention is not confined to any subset of embodiments, and is confined only by the limitations set out in the appended claims.

As used herein, the terms “vertical,” “lateral,” “upper,” “lower,” “top,” and “bottom” can refer to relative directions or positions of components of the semiconductor devices in view of the orientation shown in the drawings. For example, “bottom” can refer to a feature positioned closer to the bottom of a page than another feature. These terms, however, should be construed broadly to include semiconductor devices, and components thereof, having other orientations, such as inverted or inclined orientations where top/bottom, over/under, above/below, up/down, and left/right can be interchanged depending on the orientation.

The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

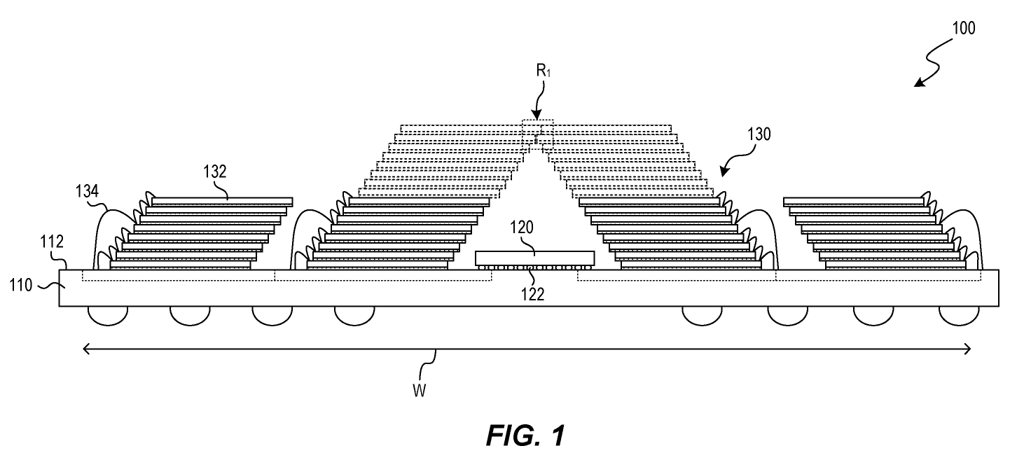

FIG. 1 is a partially schematic cross-sectional view of a stacked semiconductor device 100 with multiple single-tier die stacks. As illustrated in FIG. 1, the stacked semiconductor device 100 (“device 100”) includes a base substrate 110, as well as a controller die 120 and one or more die stacks 130 (four illustrated in FIG. 1) carried by an upper surface 112 of the base substrate 110. The controller die 120 (sometimes also referred to herein as a “controller”) is electrically/communicably and physically coupled to the base substrate 110 via a plurality of conductive structures 122 (e.g., solder structures, conductive pillars, metal-metal bonds, and/or the like). Further, each of the die stacks 130 includes a plurality of dies 132 (e.g., memory dies such as DRAM dies and/or NAND dies, logic dies, processing dies, and/or the like) that are staggered (e.g., stacked in a shingle formation) with respect to each other. As a result, each of the dies 132 can be communicably coupled to the base substrate 110 via one or more wire bonds 134.

In the environment illustrated in FIG. 1, each of the die stacks 130 includes eight of the dies 132 arranged in a single-tier configuration (e.g., a single set of staggered dies with the same offset between each of the dies). As a result, the device 100 includes a total of thirty-two of the dies 132 within a given longitudinal footprint (e.g., within a width W and length (into the page) of the base substrate 110). As industry demands for increased memory and/or increased performance continue, it would be valuable to include additional dies into the device 100. However, as illustrated in region R₁ of FIG. 1, the increase within the illustrated width W is limited before the die stacks 130 run into each other. Accordingly, further increases would require an increase in the width W of the base substrate 110 to provide additional space for the die stacks 130. Said another way, the longitudinal footprint of the base substrate 110 (and therefore the device 100) must increase to meet demands for increased capacity within the device 100. As a result, however, the density of the device (e.g., the memory density) available within a given longitudinal footprint is limited by the eventual overlap in the die stacks 130.

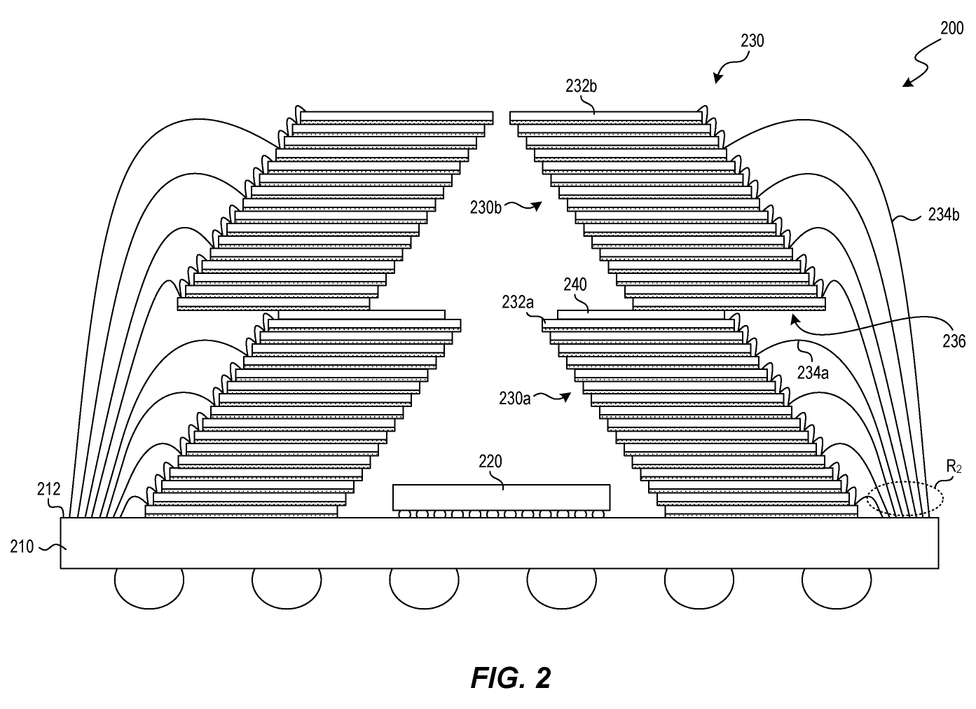

FIG. 2 is a partially schematic cross-sectional view of a stacked semiconductor device 200 with multi-tiered die stacks. As illustrated in FIG. 2, the stacked semiconductor device 200 (“device 200”) is generally similar to the device 100 discussed above with reference to FIG. 1. For example, the device 200 illustrated in FIG. 2 includes a base substrate 210, as well as a controller 220 and one or more die stacks 230 (two illustrated in FIG. 2) integrated with (e.g., carried by and electrically/communicably coupled to) an upper surface 212 of the base substrate 210. In the illustrated embodiment, however, each of the die stacks 230 includes a first tier 230a, a second tier 230b carried by the first tier 230a, and a spacer component 240 positioned between the first tier 230a and the second tier 230b. The first tier 230a (sometimes also referred to herein as a “first portion”) includes a plurality of first dies 232a that are staggered with respect to each other, allowing each of the first dies 232a to be coupled to the base substrate via first wire bonds 234a. Similarly, the second tier 230b (sometimes also referred to herein as a “second portion”) includes a plurality of second dies 232b that are staggered with respect to each other, allowing each of the second dies 232b to be coupled to the base substrate via second wire bonds 234b.

As further illustrated in FIG. 2, the second tier 230b of each of the die stacks 230 is offset from the first tier 230a. The offset allows the die stacks 230 to avoid collision (e.g., as illustrated in the first region R₁ of FIG. 1) while incorporating additional dies into the device 200. As a result, for example, the offset can help the device 200 meet continuing demands to increase overall memory and/or memory within a given longitudinal footprint. The offset, however, results in each of the die stacks 230 including an overhanging portion 236. The overhanging portion 236 creates instability in the die stacks 230 between the first and second tiers 230a, 230b. The instability, in turn, can cause the die stacks 230 to collapse during a stacking process and/or another manufacturing process, thereby reducing throughput and/or increasing the cost of manufacturing. Additionally, or alternatively, the instability provides a weak point in the die stacks 230 that can reduce the lifespan of the device 200.

As further illustrated in FIG. 2, the multi-tiered design of the die stacks 230 requires long wire bonds for the second wire bonds 234b and/or crowing where the first and second wire bonds 234a, 234b are coupled to the base substrate 210. As a result, manufacturing processes for the device 200 often encounter wire-sweep issues in a second region R₂ that undermine (or destroy) the functionality of the device 200.

Stacked semiconductor devices, and associated systems and methods, that address the problems discussed above with reference to FIGS. 1 and 2 are disclosed herein. For example, as discussed in more detail below, stacked semiconductor devices according to the present technology can include multi-tiered die stacks with inverse staggering between tiers, thereby creating wing-shaped die stacks and/or an x-shaped wing for the packages overall. Further, the stacked semiconductor devices disclosed herein can include an elevated redistribution layer (RDL) interposer to help provide a bridge between the upper tier(s) of the die stacks and the base substrate and/or the controller. Additional details on the stacked semiconductor devices, and associated systems and methods, are discussed below with reference to FIGS. 3–5.

FIG. 3 is a partially schematic cross-sectional view of a stacked semiconductor device 300 configured in accordance with embodiments of the present technology. As illustrated in FIG. 3, the stacked semiconductor device 300 (“device 300,” sometimes also referred to herein as a “stacked semiconductor package”) includes a base substrate 310, as well as a controller 320, an RDL interposer 330, and one or more die stacks 350 (two illustrated in FIG. 3) each integrated with (e.g., carried by and coupled to) an upper surface 312 of the base substrate 310. Further, the device 300 can include a mold material 370 (e.g., an epoxy-based encapsulant and/or any other suitable material) deposited over the upper surface 312, the controller 320, the RDL interposer 330, and the die stacks 350. The base substrate 310 can be a package substrate (e.g., printed circuit board, a prepreg substrate, and/or the like), a silicon interposer, and/or any other suitable substrate to integrate with the controller 320, the RDL interposer 330, and the die stacks 350.

In the illustrated embodiments, the controller 320 (e.g., a controller die) is integrated with a central portion of the upper surface 312 of the base substrate 310 via a plurality of first conductive structures 342. The first conductive structures 342 can include solder structures (e.g., solder balls, micro bumps, and/or the like), conductive pillars, metal-metal bonds, and/or the like. Similarly, the RDL interposer 330 (sometimes also referred to herein as a “redistribution interposer,” an “interposer substrate,” an “elevated interposer,” and/or the like) is integrated with the central portion of the upper surface 312 of the base substrate 310 via a plurality of second conductive structures 344. Further, the second conductive structures 344 can include solder structures (e.g., solder balls, solder columns, and/or the like), conductive pillars, metal-metal bonds, and/or the like.

In various embodiments, a base material of the RDL interposer 330 can include a silicon substrate, an embedded trace substrate (ETS), a prepreg substrate, and/or any other suitable substrate. As further illustrated in FIG. 3, the RDL interposer can include an upper surface 332 at a height H above the upper surface 312 of the base substrate 310 and a lower surface 334 opposite the upper surface 332. Further, the RDL interposer 330 can include one or more bond sites 336 (two illustrated in the cross-section of FIG. 3) at the upper surface 332 and/or one or more bond sites 336 (two illustrated in the cross-section of FIG. 3) at the lower surface 334, as well as one or more metallization layers 338 electrically coupling respective pairs of the bond sites 336. Further, in some embodiments, as discussed in more detail below, the metallization layers 338 include trace-matching paths to help establish equal path lengths between the controller 320 and individual dies 352 in the die stacks 350.

In the illustrated embodiment, the device 300 includes two die stacks 350 carried by peripheral portions of the upper surface 312 of the base substrate 310. The die stacks 350 are positioned on opposite sides of the RDL interposer 330 (and the controller 320). Further, each of the die stacks 350 includes a plurality of the individual dies 352 stacked into a first tier 354a and a second tier 354b. The individual dies 352 in the first tier 354a are each laterally offset from each other in a first direction (e.g., from a periphery of the device 300 toward a center of the device 300), and the individual dies 352 in the second tier 354b are each laterally offset from each other in a second direction opposite the first direction (e.g., from the center of the device 300 toward the periphery of the device 300). As a result, each of the die stacks 350 has a wing-shaped construction. Still further, the die stacks 350 are mirrored from each other, providing an x-shaped wing construction for the die stacks 350 overall.

As further illustrated in FIG. 3, each of the individual dies 352 in the first tier 354a are communicably/electrically coupled to first substrate bond sites 316 at the upper surface 312 of the base substrate 310 via one or more first wire bonds 362. The first substrate bond sites 316 (e.g., bond pads formed at the upper surface 312), in turn, are coupled to the controller 320 via one or more metallization layers 318 (e.g., signal route lines) formed in the base substrate 310, thereby establishing first communication paths to each of the individual dies 352 in the first tier 354a. In contrast, each of the individual dies 352 in the first tier 354a are communicably/electrically coupled to the bond sites 336 at the upper surface 332 of the RDL interposer 330 via one or more second wire bonds 364. As discussed above, the bond sites 336 at the upper surface 332 are coupled to the bond sites 336 at the lower surface 334 via the metallization layers 338. The bond sites 336 at the lower surface 334, in turn, are coupled to second substrate bond sites 317 at the upper surface 312 of the base substrate 310 via the second conductive structures 344. The second substrate bond sites 317, in turn, are coupled to the controller 320 via the one or more metallization layers 318, thereby establishing second communication paths to each of the individual dies 352 in the second tier 354b.

The multi-tier design of the die stacks 350 can allow the die stacks 350 to increase in height (e.g., up to at least 32 dies per die stack). As a result, the device 300 can include more of the individual dies 352 in a given longitudinal footprint and/or can have an increased memory density within the given longitudinal footprint. The wing-shaped design of the die stacks 350, however, can help stabilize the die stacks 350 by eliminating the overhanging portion 236 discussed above with reference to FIG. 2. As a result, each of the die stacks 350 can be more stable than the die stacks 230 discussed above with reference to FIG. 2. In turn, the die stacks 350 can be less likely to fail during manufacturing and/or can help improve an expected lifespan of the device 300 (e.g., by being less likely to fail under stress during operation). Further, the wing-shaped design of the die stacks 350 can help reduce the occurrence of wire sweep issues since the first wire bonds 362 and the second wire bonds 364 are formed in different locations. Still further, the RDL interposer 330 provides a solid device connection between the second wire bonds 364 and the base substrate 310, beginning at the height H above the base substrate 310. The solid connection provided by the RDL interposer 330 helps reduce the overall length of the second wire bonds 364, thereby further reducing the chance of wire sweep issues in the device 300. Additionally, or alternatively, the solid connection provided by the RDL interposer 330 can help improve the stability of the device 300 overall, further helping extend the expected lifespan of the device 300.

In some embodiments, the metallization layers 318 in the base substrate 310 and/or the metallization layers 338 in the RDL interposer 330 can be configured to match signal paths between various individual dies in the die stacks 350. For example, the metallization layers 318 in the base substrate 310 and/or the metallization layers 338 in the RDL interposer 330 can include one or more serpentine route lines to help ensure that a first communication path to a first individual die in the first tier 354a has a generally equal length as a second communication path to a second individual die in the second tier 354b. In some embodiments, the metallization layers 318 in the base substrate 310 and/or the metallization layers 338 in the RDL interposer 330 match the path lengths for corresponding pairs of dies in the first and second tiers 354a, 354b.

In the embodiments illustrated in FIG. 3, the RDL interposer 330 is positioned directly over the controller 320. Additionally, the second conductive structures 344 are positioned peripheral to the controller 320 with respect to a center of the base substrate 310. As a result, the controller 320 is positioned fully beneath the RDL interposer 330. That is, the controller 320 can be positioned fully within a footprint of the RDL interposer 330 such that the controller 320 and the RDL interposer 330 do not require the base substrate 310 to be expanded to accommodate both features. Further, the x-wing shape of the die stacks 350 illustrated in FIG. 3 allows the RDL interposer 330 to be positioned beneath at least a portion of the die stacks 350 (e.g., beneath a portion of the individual dies 352 in the first tier 354a), with an innermost edge 355 of the die stacks 350 overhanging (e.g., vertically aligned with) a portion of the RDL interposer 330. Said another way, the RDL interposer 330 can be positioned at least partially within the longitudinal footprint of the die stacks 350. As a result, the x-wing shape of the die stacks 350 can help reduce a size of the device 300 required to provide a given level of semiconductor functioning (e.g., memory, processing capacity, and/or the like) and/or can help increase a density of the semiconductor functioning. In some embodiments, as further illustrated in FIG. 3, the controller 320 is also positioned at least partially within the longitudinal footprint of the die stacks 350, thereby further enabling size reductions and/or increases in density.

As further illustrated in FIG. 3, the base substrate 310 can further include one or more metallization features 319 extending between the upper surface 312 (sometimes also referred to herein as the “active surface,” “frontside,” and/or the like) to the lower surface 314 (sometimes also referred to herein as the “backside,” “back surface,” and/or the like). The metallization features 319 can include metallization layers, route lines, through substrate vias (TSVs), and/or any other suitable component. As a result, for example, the metallization features 319 can couple the controller 320 (and/or any other suitable component) to one or more package connections 390 (e.g., solder structures, bond sites, conductive pillars, and/or the like) at the lower surface 314 of the base substrate 310. The package connections 390, in turn, can be coupled to various devices external to the device 300.

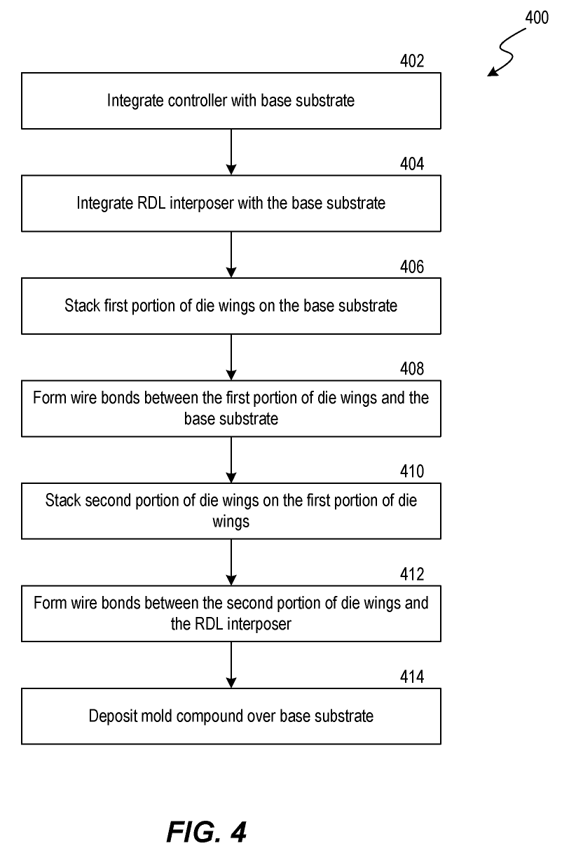

FIG. 4 is a flow diagram of a process 400 for manufacturing a stacked semiconductor device in accordance with embodiments of the present technology. The process 400 can be implemented by a single manufacturing apparatus and/or split between multiple manufacturing apparatuses to stacked semiconductor devices with wing-shaped die stacks and/or elevated interposers.

The process 400 begins at block 402 by integrating a controller (e.g., the controller 320 of FIG. 3) with a base substrate (e.g., the base substrate 310 of FIG. 3). Integrating the controller can include stacking the controller on the base substrate and forming electrical and/or physical connections between the controller and the base substrate. Forming the connections can include a reflow process for one or more solder structures, an annealing process to form metal-metal connections and/or substrate-substrate connections, and/or any other suitable bonding process.

At block 404, the process 400 includes integrating an RDL interposer (e.g., the RDL interposer 330 of FIG. 3) with the base substrate. The integration process at block 404 can include positioning the RDL interposer (e.g., a silicon interposer) over the controller (e.g., such that the controller is fully beneath the interposer). Similar to the discussion above, the process 400 can then include forming electrical and/or physical connections between the controller and the base substrate. Forming the connections can include a reflow process for one or more solder structures, an annealing process to form metal-metal connections and/or substrate-substrate connections, and/or any other suitable bonding process.

At block 406, the process 400 includes stacking a first portion of one or more die wings (e.g., the first tier 354a of the die stacks 350 of FIG. 3) on the base substrate adjacent to the RDL interposer and the controller. In some embodiments, the stacking process includes stacking dies individually (e.g., one by one) and/or in subsets of the first portion. For each of the die wings, the dies are staggered in a first direction as they are stacked (and/or are pre-staggered in the first direction when stacked in subsets and/or altogether). In some embodiments, the upper dies in the first portion of the die wings overhang the RDL interposer and/or the controller as they are stacked. At block 408, the process 400 includes forming first wire bonds between each of the dies in the first portion of the die wings and the base substrate. As a result, each of the dies in the first portion is carried by and electrically/communicably coupled to the base substrate. The base substrate, in turn, can electrically couple the dies in the first portion of the die wings to the controller (e.g., via the metallization layers 318 of FIG. 3).

At block 410, the process 400 includes stacking a second portion of the die wings (e.g., the second tier 354b of the die stacks 350 of FIG. 3) on the base substrate on top of the first portion. In some embodiments, the stacking process includes stacking dies individually (e.g., one by one) and/or in subsets of the second portion. For each of the die wings, the dies in the second portion are staggered in a second direction that is opposite to the first direction as they are stacked. As a result, each of the die wings can have a balanced wing shape once complete. At block 412, the process 400 includes forming second wire bonds between each of the dies in the second portion of the die wings and the RDL interposer. As discussed above with reference to FIG. 3, the RDL interposer electrically couples the dies in the second portion of the die wings to the base substrate. The base substrate, in turn, electrically couples the dies in the second portion of the die wings to the controller.

At block 414, the process 400 includes depositing a mold compound over the base substrate to cover the controller, the RDL interposer, and each of the die wings. The mold compound can include an epoxy-based resin and/or any other suitable material to protect and/or insulate the components of the stacked semiconductor device.

Although blocks 402–414 are illustrated and discussed with reference to FIG. 4 in a particular order, one of skill in the art will understand that the technology disclosed herein is not so limited. Purely by way of example, the first and second portions of the die wings can each be stacked on the base substrate before forming any wire bonds (e.g., by executing blocks 406 and 410 generally simultaneously). Indeed, in some embodiments, each of the die wings includes a pre-packaged stack of dies for the first and second portions of the die wings. In a related example, the controller and the RDL interposer can be integrated with the base substrate in a single process (e.g., implementing blocks 402 and 404 generally simultaneously). For example, the controller and RDL interposer can both be placed on the base substrate before being connected to the base substrate in a single reflow process. Additionally, or alternatively, it will be understood that the process 400 can include various additional steps and/or sub-processes and/or omit various steps and/or processes. Purely by way of example, as discussed in more detail below, the controller and RDL interposer can be integrated into a sub-package (e.g., with the controller integrated with the RDL interposer). In such embodiments, the sub-package is stacked on the base substrate, and then the RDL interposer is connected to the base substrate (e.g., via a reflow process, a metal-metal bonding process, and/or the like). That is, the process 400 can omit block 402 because the controller is integrated with the RDL interposer rather than the base substrate. In another example, the process 400 can include integrating various other electrical components (e.g., capacitors) with the base substrate before depositing the mold compound at block 414.

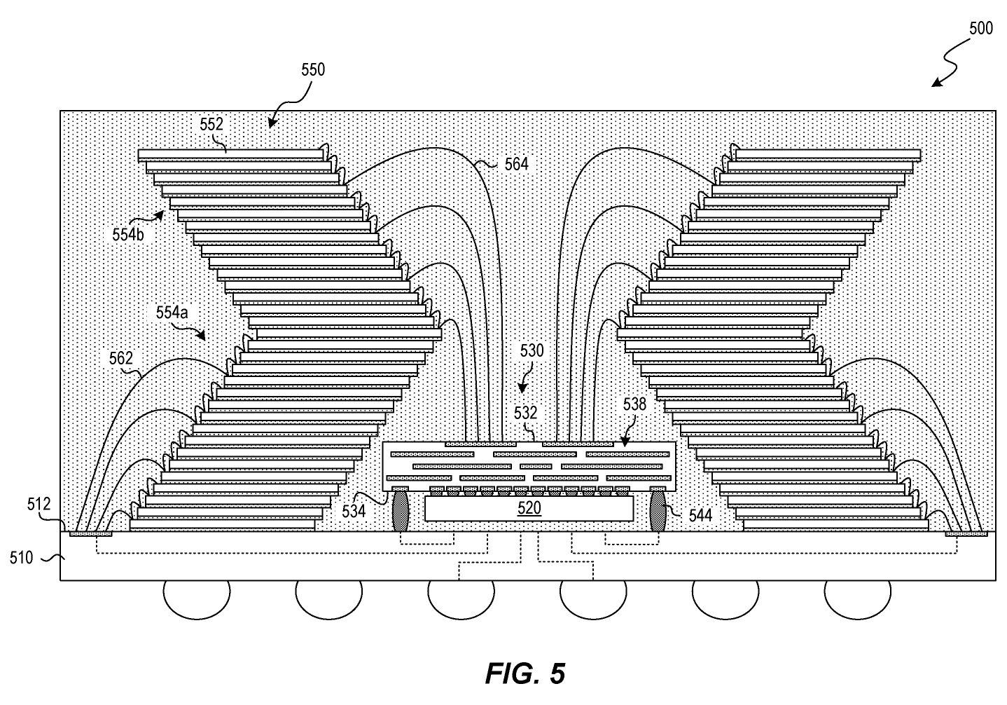

FIG. 5 is a partially schematic cross-sectional view of a stacked semiconductor device 500 configured in accordance with embodiments of the present technology. In the illustrated embodiments, the stacked semiconductor device 500 (“device 500”) is generally similar to the device 300 discussed above with reference to FIG. 3. For example, the device 500 includes a base substrate 510, as well as a controller 520, an RDL interposer 530, and one or more die stacks 550 (two illustrated in FIG. 5) carried by an upper surface of the base substrate 510. The RDL interposer 530 is integrated with the upper surface 512 (sometimes also referred to herein as an “active surface,” “frontside,” and/or the like) by conductive structures 544 (e.g., solder balls, conductive columns, and/or the like). Further, each of the die stacks 550 has a wing-shaped configuration. That is, each of the die stacks 550 includes a first portion 554a (e.g., a first tier) staggered in a first direction and a second portion 554b (e.g., a second tier) carried by the first portion 554a and staggered in a second direction opposite the first direction. Individual dies 552 in the first portion 554a are coupled to the upper surface 512 of the base substrate 510 by first wire bonds 562 and the individual dies 552 in the second portion 554b are coupled to an upper surface 532 of the RDL interposer 530 by second wire bonds 564.

In the illustrated embodiments, however, the controller 520 is integrated with a lower surface 534 of the RDL interposer 530. The controller 520 is then communicably/electrically coupled to the base substrate 510 via metallization layers 538 (e.g., signal route lines) in the RDL interposer and the conductive structures 544. In some embodiments, the RDL interposer 530 is an embedded trace substrate (ETS) to help accommodate additional route lines for the controller 520. By packaging the RDL interposer 530 and the controller 520 together, the device 500 can be constructed in a streamlined packaging process, which in turn can help increase throughput and/or help increase an expected lifespan for the device 500.

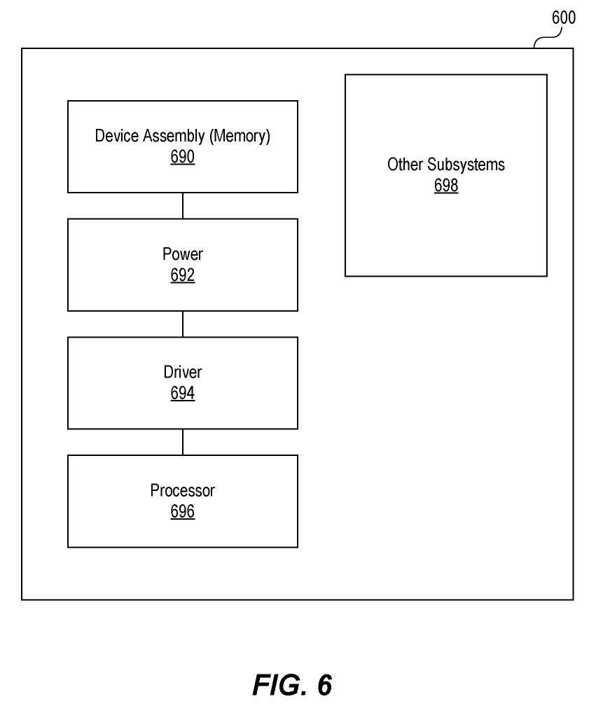

FIG. 6 is a schematic view of a system 600 that includes a semiconductor package configured in accordance with embodiments of the present technology. That is, the semiconductor packages discussed above can be incorporated into any of a myriad of larger and/or more complex systems, a representative example of which is system 600, shown schematically in FIG. 6. The system 600 can include a memory 690 (e.g., SRAM, DRAM, flash, and/or other memory devices), a power supply 692, a drive 694, a processor 696, and/or other subsystems or components 698. Semiconductor packages of the type discussed above with reference to FIGS. 3 and 5 and/or manufactured using processes of the type discussed above with reference to FIG. 4 can be included in any of the elements shown in FIG. 6. Purely by way of example, the stacked semiconductor device 300 of FIG. 3 can be deployed in the memory 690 (e.g., in a managed NAND for us in various consumer electronics, automotive electronics, and the like; an SSD package; and/or any other suitable memory device).

The resulting system 600 can be configured to perform any of a wide variety of suitable computing, processing, storage, sensing, imaging, and/or other functions. Accordingly, representative examples of the system 600 include, without limitation, computers and/or other data processors, such as desktop computers, laptop computers, Internet appliances, hand-held devices (e.g., palm-top computers, wearable computers, cellular or mobile phones, automotive electronics, personal digital assistants, music players, etc.), tablets, multi-processor systems, processor-based or programmable consumer electronics, network computers, and minicomputers. Additional representative examples of the system 600 include lights, cameras, vehicles, etc. With regard to these and other examples, the system 600 can be housed in a single unit or distributed over multiple interconnected units, e.g., through a communication network. The components of the system 600 can accordingly include local and/or remote memory storage devices and any of a wide variety of suitable computer-readable media.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally,” “approximately,” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A stacked semiconductor device, comprising:
a base substrate;
a controller die;
an interposer substrate positioned directly over the controller die, the interposer substrate having a lower surface and an upper surface opposite the lower surface, wherein the lower surface is integrated with an active surface of the base substrate via conductive structures positioned peripheral to the controller die with respect to a center of the base substrate; and
a plurality of dies carried by the active surface of the base substrate adjacent to the controller die, wherein the plurality of dies comprises:
a first tier that includes a plurality of first dies staggered in a first direction, wherein each of the plurality of first dies is electrically coupled to the active surface via one or more first wire bonds; and
a second tier carried by the first tier that includes a plurality of second dies staggered in a second direction opposite the first direction, wherein each of the plurality of second dies is electrically coupled to the upper surface of the interposer substrate via one or more second wire bonds.

2. The stacked semiconductor device of claim 1 wherein the interposer substrate comprises a plurality of metallization layers between the upper surface and the lower surface, and wherein the plurality of metallization layers include a plurality of route lines configured to match a second signal path length for each of the plurality of second dies to a first signal path length for a corresponding die from the plurality of first dies.

3. The stacked semiconductor device of claim 1 wherein the interposer substrate is at least partially vertically aligned with one or more first dies from the plurality of first dies.

4. The stacked semiconductor device of claim 1 wherein the plurality of dies form a first die stack on the base substrate, wherein the first die stack is carried by the active surface of the base substrate adjacent to a first side of the controller die, and wherein the stacked semiconductor device further comprises a second die stack carried by the active surface of the base substrate adjacent to a second side of the controller die opposite the first side.

5. The stacked semiconductor device of claim 4 wherein the second die stack comprises:
a third tier that includes a plurality of third dies staggered in the second direction, wherein each of the plurality of third dies is electrically coupled to the active surface via one or more third wire bonds; and
a fourth tier carried by the third tier that includes a plurality of fourth dies staggered in the first direction, wherein each of the plurality of fourth dies is electrically coupled to the upper surface of the interposer substrate via one or more fourth wire bonds.

6. The stacked semiconductor device of claim 4 wherein at least a first portion of the first die stack overhangs the interposer substrate, and wherein at least a second portion of the second die stack overhangs the interposer substrate.

7. The stacked semiconductor device of claim 1 wherein the controller die is integrated with the active surface of the base substrate and communicably coupled to the interposer substrate via one or more route lines in the active surface.

8. The stacked semiconductor device of claim 1 wherein the controller die is integrated with the lower surface of the interposer substrate.

9. A semiconductor device package, comprising:
a base substrate having a front surface;
a controller integrated with the front surface;
a redistribution interposer carried by the front surface of the base substrate over the controller; and
a wing-shaped die stack carried by the front surface adjacent to the controller, wherein:
a first portion of the wing-shaped die stack is coupled to the controller via a first communication path; and
a second portion of the wing-shaped die stack is coupled to the controller via a second communication path different from the first communication path, wherein the second communication path comprises one or more route lines in the redistribution interposer.

10. The semiconductor device package of claim 9 wherein the wing-shaped die stack is a first wing-shaped die stack carried by the front surface adjacent to a first side of the controller, wherein the semiconductor device package further comprises a second wing-shaped die stack carried by the front surface adjacent to a second side of the controller opposite the first side.

11. The semiconductor device package of claim 10 wherein the first wing-shaped die stack has a first staggered profile, and wherein the second wing-shaped die stack has a second staggered profile mirrored from the first staggered profile.

12. The semiconductor device package of claim 9 wherein one or more dies in the first portion of the wing-shaped die stack overhang the redistribution interposer.

13. The semiconductor device package of claim 9 wherein each die in the second portion of the wing-shaped die stack is communicably coupled to the redistribution interposer via one or more wire bonds extending between the second portion and an upper surface of the redistribution interposer.

14. The semiconductor device package of claim 9 wherein:
for each die in the first portion of the wing-shaped die stack, the first communication path has a first path length; and
for each die in the second portion of the wing-shaped die stack, the second communication path has a second path length generally equal to the first path length.

15. The semiconductor device package of claim 14 wherein the one or more route lines in the second communication path are configured to match the second path length to the first path length.

16. The semiconductor device package of claim 9 wherein the redistribution interposer is integrated with the front surface via one or more conductive structures positioned peripherally around the controller.

17. A method for manufacturing a stacked semiconductor device, the method comprising:
integrating a controller with an active surface of a base substrate;
integrating a redistribution layer interposer with the active surface of the base substrate; and
for each of two or more die wings:
stacking a first portion of the two or more die wings on the active surface of the base substrate adjacent to the controller;
forming first wire bonds between the first portion and one or more first bond pads on the active surface of the base substrate;
stacking a second portion of the two or more die wings on the first portion of the two or more die wings; and
forming second wire bonds between the second portion and one or more second bond pads on an upper surface of the redistribution layer interposer.

18. The method of claim 17 wherein, for each of the two or more die wings:
stacking the first portion of the two or more die wings on the active surface of the base substrate adjacent comprises staggering each die in the first portion in a first direction; and
stacking the second portion of the two or more die wings on the first portion of the two or more die wings comprises staggering each die in the second portion in a second direction opposite the first direction.

19. The method of claim 17 wherein, for each of the two or more die wings, stacking the first portion of the two or more die wings on the active surface of the base substrate comprises at least partially overhanging one or more dies over the redistribution layer interposer.

20. The method of claim 17 wherein integrating the redistribution layer interposer with the active surface of the base substrate comprises positioning the redistribution layer interposer directly over the controller.
